(19) United States
(12) Patent Application Publication
(10) Pub. No.: US 2017/0117263 A1
(43) Pub. Date: Apr. 27, 2017

(54) MOLDED INTERCONNECTING SUBSTRATE AND THE METHOD FOR MANUFACTURING THE SAME

(71) Applicant: POWERTECH TECHNOLOGY INC., Hsinchu (TW)

(72) Inventors: Yun-Hsin YEH, Hsinchu (TW); Hung-Hsin HSU, Hsinchu (TW); Chia-Yu HUNG, Hsinchu (TW)

(21) Appl. No.: 15/190,712

(22) Filed: Jun. 23, 2016

(30) Foreign Application Priority Data
Oct. 21, 2015 (TW) 104134479

(51) Int. Cl. H01L 25/00; H01L 23/498; H01L 25/065; H01L 23/538; H01L 21/48; H01L 21/56

(52) U.S. Cl. CPC H01L 25/50; H01L 21/486; H01L 21/563; H01L 21/568; H01L 25/0657; H01L 23/5383; H01L 23/5384; H01L 23/5386; H01L 23/5389; H01L 23/49805; H01L 23/49811; H01L 23/49827; H01L 2021/60262

(57) ABSTRACT

A molded interconnecting substrate has an embedded redistribution layer (RDL), an embossed RDL, a plurality of conductive pillars encapsulated in a molding core, and a chip also encapsulated in the molded core. The conductive pillars are disposed on the external pads of the embedded RDL. The chip is die-bonded onto the embedded RDL. The molding core has an external surface and an opposing component-installing surface. The embedded RDL is embedded in the molding core from the external surface. The bottom surface of the embedded RDL is coplanar to the external surface and the pillar-top surfaces of the conductive pillars are coplanar to the component-installing surface. The embossed RDL is disposed on and extruded from the component-installing surface including a plurality of pillar-top pads aligned and bonded to the pillar-top surfaces. Accordingly, it is possible to eliminate a flip-chip molding thickness without manufacture of substrate plating lines where fine-pitch substrate circuitry can be achieved without substrate drilling process.

### FIELD OF THE INVENTION

The present invention relates to a circuit board to carry electronic devices and more specifically to a molded interconnecting substrate and the method for manufacturing the same.

### BACKGROUND OF THE INVENTION

In the existing flip-chip package, chips are flip-chip die-bonded to a substrate where the bumps on the chips are physically and electrically connected to the substrate. However, the overall package height remains substantially the same.

Printed circuit boards (PCB) are key components for various electronic products where one of its purposes is to carry various electronic components and to transmit signals among the electronic components. A PCB can generally be categorized into multi-layer PCB, High Density Interconnect (HDI) PCB, High Level Circuitry (HLC) PCB, Flexible Printed Circuitry (FPC) PCB, and Rigid-Flex PCB. The core materials of the PCB is BT resin.

As shown in FIG. 1, a conventional flip-chip package 300 essentially consisting of a substrate 310, a chip 320 flip-chip die-bonded on the substrate 310, and a molding compound 340 to encapsulate the chip 320. The substrate 310 has a core 311 where a first circuitry layer 312 and a second circuitry layer 313 are disposed on the top surface and the bottom surface of the core 311, respectively, where the first circuitry layer 312 and the second circuitry layer 313 are electrically connected by a plurality of plated through holes 314. The chip 320 is physically and electrically connected to the second circuitry layer 313 by a plurality of bumps 321 where an under-fill material 330 is disposed to encapsulate the bumps 321. The molding compound 340 is disposed on top of the substrate 310 by molding processes where the molding compound 340 on top of the substrate 310 provided a flip-chip molding thickness of H0. A plurality of external terminals 350 are disposed on the bottom surface of the substrate 310 and are connected to the first circuitry layer 312. The manufacture of the plated through holes 314 are done firstly by drilling through the core 311 without penetrating through the first circuitry layer 312 or the second circuitry layer 313 followed by electrical plating conductive metal layers inside the plated through holes 314 and then the plated through holes 314 are filled with dielectric materials or conductive materials.

### SUMMARY OF THE INVENTION

A main purpose of the present invention is to provide a molded interconnecting substrate and the method for manufacturing the same to pre-dispose the chip inside the substrate to eliminate the flip-chip molding thickness without manufacture of substrate plating lines to achieve fine-pitch substrate circuitry without substrate drilling processes.

Another purpose of the present invention is to provide a molded interconnecting substrate and the method for manufacturing the same to dispose conductive pillars on the external pads to replace the conventional substrate plated through holes which penetrating through the circuitry with the risk of under-plated or voids issues inside the plated through holes.

According to the present invention, a molded interconnecting substrate is disclosed. The molded interconnecting substrate comprises an embedded redistribution layer (RDL), a plurality of first conductive pillars, a first chip, a first molding core, and a first embossed RDL. The embedded RDL is disposed on a molding surface and may include a plurality of embedded circuitries, a plurality of external pads, and a plurality of first internal pads. The embedded circuitries may electrically connect the corresponding external pads to the corresponding first internal pads. The first conductive pillars are disposed on the external pads. The first chip is coupled to the embedded RDL and is electrically connected to the first internal pads. The first molding core is disposed on the molding surface to encapsulate the first chip and the first conductive pillars where the first molding surface has an external surface where the embedded RDL is embedded into the first molding core from the external surface. A plurality of bottom surfaces of the embedded circuitries, of the external pads, and of the first internal pads are coplanar to the external surface where the first molding core further has a first component-installing surface opposing to the external surface. The first conductive pillars have a plurality of first pillar-top surfaces coplanar to the first component-installing surface. The first embossed RDL is disposed on the first component-installing surface including a plurality of first embossed circuitries, a plurality of first pillar-top pads, and a plurality of second internal pads where the first pillar-top pads are aligned and bonded to the first pillar-top surfaces and the first embossed RDL is disposed on and extruded from the first component-installing surface of the first molding core. The method for manufacturing the above-mentioned molded interconnecting substrate is also revealed.

### DESCRIPTION OF THE DRAWINGS

FIG. 1 is a cross-sectional view of a conventional flip-chip package.

FIG. 2 is a cross-sectional view with a partially enlarged view of a molded interconnecting substrate according to the first embodiment of the present invention.

FIGS. 3A to 3G are cross-sectional views showing each component of a molded interconnecting substrate during each processing step according to the first embodiment of the present invention.

FIG. 4 is a cross-sectional view of a molded interconnecting substrate according to the second embodiment of the present invention.

FIGS. 5A to 5E are cross-sectional views showing each component of a molded interconnecting substrate during each processing step according to the second embodiment of the present invention.

FIG. 6 is a cross-sectional view of a stacked microelectronic device with the implementation of a molded interconnecting substrate according to the second embodiment of the present invention.

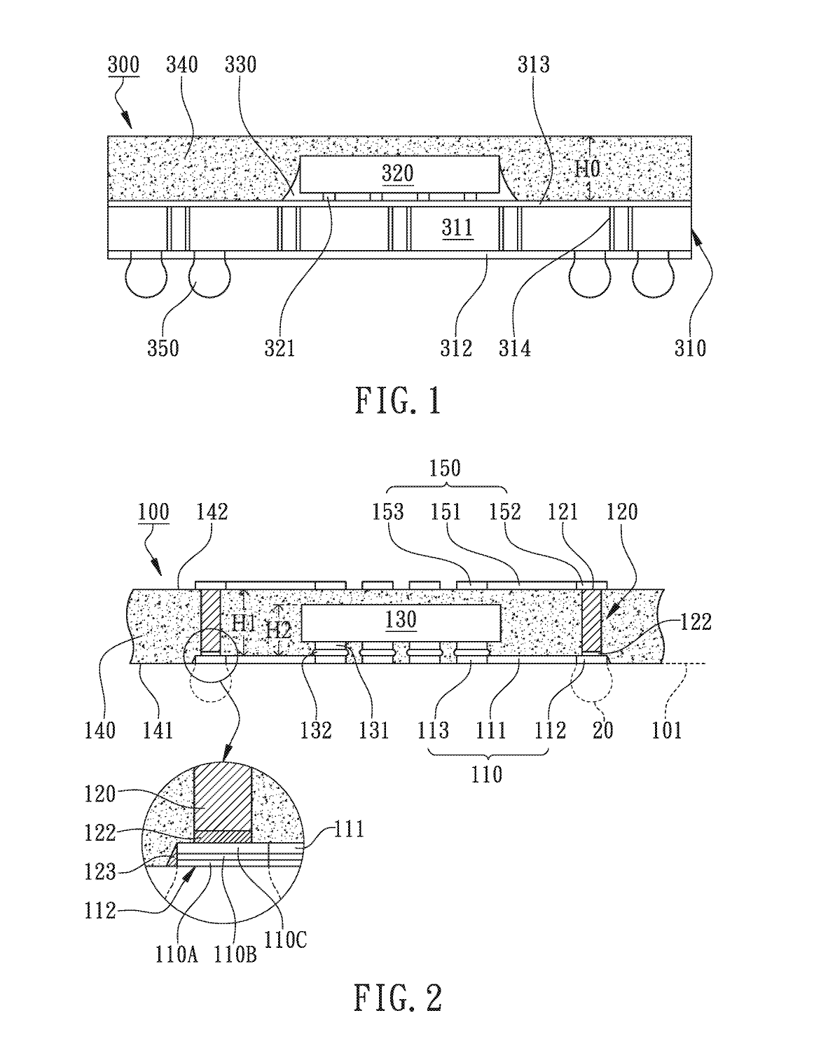

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

According to the first embodiment of the present invention, a cross-sectional view of a molded interconnecting substrate 100 is illustrated in FIG. 2 with a part of the molded interconnecting substrate 100 enlarged. A molded interconnecting substrate 100 comprises an embedded redistribution layer (RDL) 110, a plurality of first conductive pillars 120, a first chip 130, a first molding core 140, and a first embossed RDL 150.

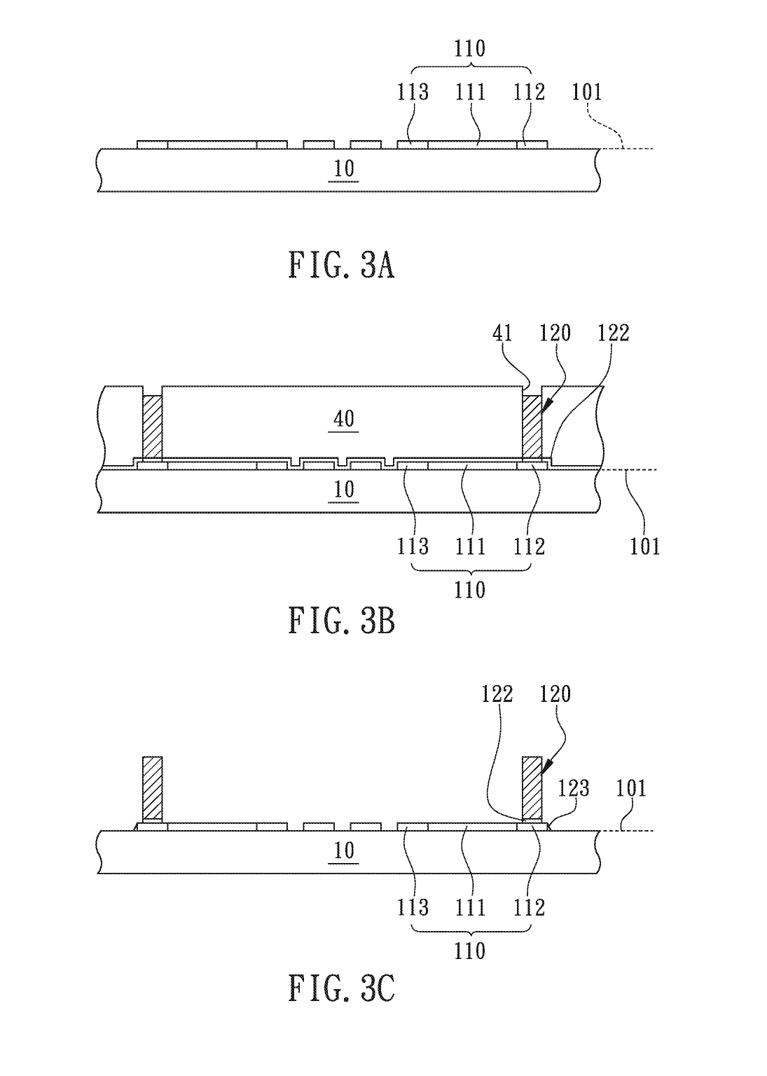

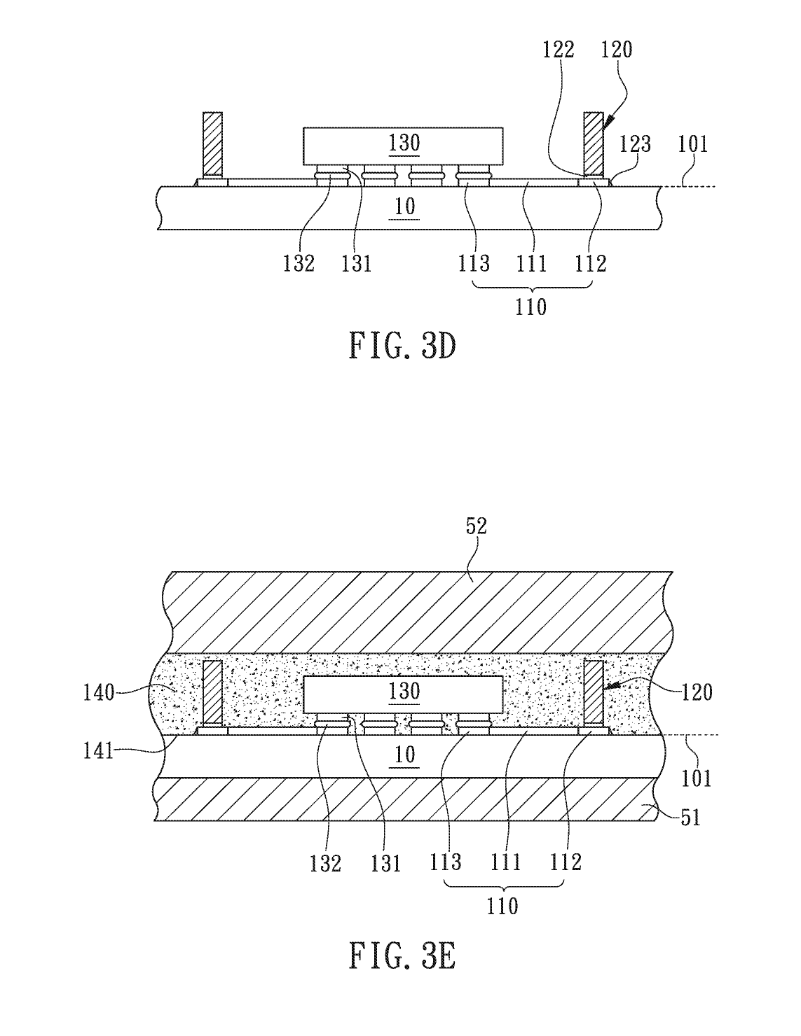

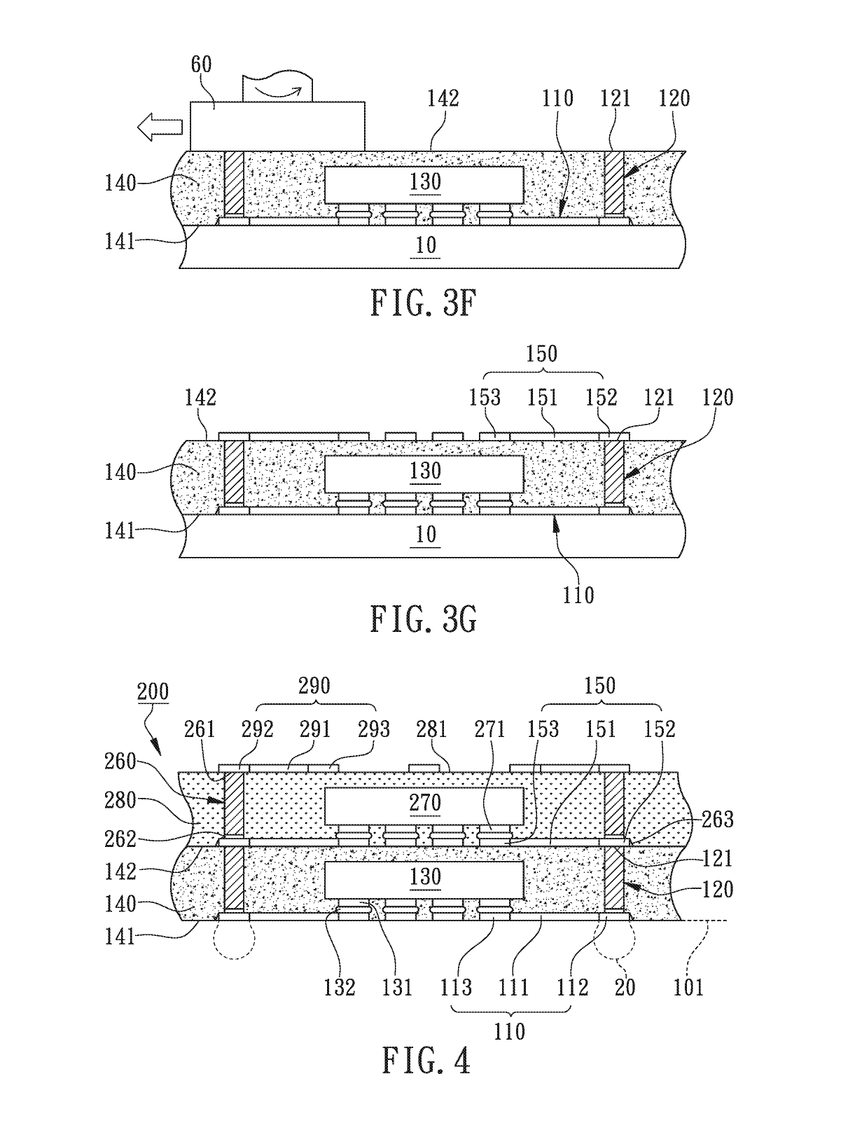

As shown in FIG. 2, the embedded RDL 110 is formed on a molding surface 101 which is provided by a temporary carrier 10 as shown in FIG. 3A. The temporary carrier 10 may be a glass, a silicon panel, or a silicon wafer. A photo-sensitive adhesive may be formed on the major surface of the temporary carrier 10. The embedded RDL 110 includes a plurality of embedded circuitries 111, a plurality of external pads 112, and a plurality of first internal pads 113. The embedded circuitries 111 electrically connect the corresponding external pads 112 to the corresponding first internal pads 113. The pitch of the external pads 112 may be larger than the pitch of the first internal pads 113. The external pads 112 are in fan-out design. The bottom surfaces of the external pads 112 may or may not be used for the placement of a plurality of external terminals 20 such as solder balls. The so-called “RDL” is a circuitry layer fabricated using semiconductor wafer process or panel fabrication process, i.e. vapor deposition process, electrical plating process, and etching process. The embedded RDL 110 may not need plating lines. The invention may not be limited to using the abovementioned processes, the embedded RDL 110 may also be fabricated through lift-off process. The so-called “formed” means that the desired solid object is formed by having liquid or gas materials coated on a carrier or on a defined surface, i.e., disposing a gas phase or a liquid phase object on a defined location to form desired solid object through chemical reaction.

The first conductive pillars 120 are disposed on the external pads 112. The so-called “disposed” includes that the “the disposed carrier” is already manufactured into an object and “the disposed object” is disposed and fixed on “the disposed carrier”. Moreover, the deposition process of “the disposed object” are executed after “the disposed carrier” is fabricated or “the disposed object” is fabricated individually before deposition process, i.e., “the disposed object” is fabricated in either gas or liquid phase on a solid object or “the disposed object” is fabricated in solid phase and is disposed on another solid object. The first conductive pillars 120 has a height H1 equivalent to the thickness of the first molding core 140 apart from the thickness of the embedded RDL 110. The first conductive pillars 120 may not penetrate through the embedded RDL 110. The materials of the first conductive pillars 120 may be copper and the shape of the first conductive pillars 120 may be cylinder, tetrahedron, hexahedron, octahedron, or other polyhedron. Wherein, cylinder may be preferred to reduce the resistance of mold flow during molding process. Preferably, an electrical plating seed layer 122 is formed between the first conductive pillars 120 and the external pads 112 to enhance the electrical plating of the first conductive pillars 120. The electrical plating seed layer 122 includes a plurality of seed layer residue rings 123 to surround the periphery of the external pads 112. In this way, the external pads 112 are firmly fixed and may not be affected by the mold flow during the formation of the first molding core 140.

As shown in FIG. 2, the first chip 130 is die-bonded on the embedded RDL 110 and is electrically connected to the first internal pads 113. The so-called “bonded” meant that “the bonded object” and “the object to be bonded on” are individually fabricated to be objects, then “the bonded object” is then disposed on “the object to be bonded on”, i.e., solid to solid bonding. The first chip 130 has a chip disposed height H2. In an embodiment, the first chip 130 has a plurality of bumps 131. The plurality of bumps 131 are flip-chip die-bonded to the first internal pads 113 of the embedded RDL 110 through a solder paste 132. In this way, the bumps 131 are physically and electrically connected to the corresponding first internal pads 113. Therefore, before the formation of the first molding core 140, the first internal pads 112 are firmly fixed beforehand without affected by the mold flow. The first chip 130 is specific a semiconductor IC component.

As shown in FIG. 2, the first molding core 140 is formed on the molding surface 101 to encapsulate the first chip 130 and the first conductive pillars 120. The first molding core 140 has an external surface 141 where the embedded RDL 110 is embedded into the external surface 141 of the first molding core 140. A bottom surface of the embedded circuitries 111, of the external pads 112, and of the first internal pads 113 are coplanar to the external surface 141. The first molding core 140 further has a first component-installing surface 142 opposing to the external surface 141. Each of the first conductive pillars 120 has a first pillar-top surface 121 coplanar to a first component-installing surface 142. In the embodiment, the first molding core 140 can be a single-layer structure formed by a molding compound to simplify the structure of the substrate core. However, the first molding core 140 could also be formed by compression molding or transfer molding where the major material of the first molding core 140 is thermosetting epoxy resin.

As shown in FIG. 2, the first embossed RDL 150 is formed on the first component-installing surface 142. The first embossed RDL 150 may have a plurality of first embossed circuitries 151, a plurality of first pillar-top pads 152, and a plurality of second internal pads 153. Each of the first embossed circuitries 151 is directly coupled to a corresponding first pillar-top pad 152 and a corresponding second internal pad 153. The first pillar-top pads 152 may be aligned and bonded to the first pillar-top surfaces 121. The first embossed RDL 150 is formed on and extruded from the first component-installing surface 142 of the first molding core 140. When another chip (i.e. same as the first chip 130) is to be disposed on the first component-installing surface 142, the second internal pads 153 may be vertically aligned to the first internal pads 113. The height H1 of the first conductive pillars from the first pillar-top surfaces 121 of the first conductive pillars 120 to the external pads 112 may be greater than the chip disposed height H2 of the first chip 130. In this way, the first chip 130 is completely encapsulated inside the first molding core 140. In addition, there is no exposed surface of the first conductive pillars 120 due to the top and bottom coverage by the first pillar-top pads 152 and by the external pads 112 respectively and due to the encapsulation of the first molding core 140.

According to the molded interconnecting substrate 100, the first chip 130 may be pre-disposed inside the substrate structure to eliminate a flip-chip molding thickness. Furthermore, there is no need to manufacture electrical plating lines to achieve fine-pitch substrate circuitries and the substrate drilling process may also be eliminated. Moreover, the conventional plated through holes of the substrate may be replaced by the first conductive pillars 120 disposed on the external pads 112. The conventional plated through holes of substrate which penetrates through the circuitries has the risk of under-plating or having void issues inside the plated through holes.

As shown in FIG. 2, the embedded RDL 110 may be formed through a reversed deposition of multiple metal layers. The reversed deposition of multiple metal layers may be implemented according to the sequence of the metal deposition process materials used to form the embedded RDL 110, of which includes an adhesive layer 110A made of gold (Au), a barrier layer 110B made of nickel (Ni), and a major wiring structure 110C made of copper (Cu). The fabrication of the embedded RDL 110 is formed through reverse deposition process in a sequence of Au deposition, Ni deposition, patterned Cu plating, and dry etching. The conventional substrate circuitry layer has copper circuitry with Ni—Au plated on the external pads. The conventional substrate circuitry layer uses a normal deposition in a sequence of patterned Cu etching, covering of the circuitry outside the external pads by solder mask, electrical plating of Ni and electrical plating of Au. Therefore, the embedded RDL 110 including the corresponding external pads 112 may function as a barrier layer and an adhesive layer when fabricated without extra electrical plating process to electrically plate Ni and Au layers on the exposed surfaces of the external pads after the formation of the substrate.

The method of manufacturing the above-mentioned molded interconnecting substrate 100 is described in detail as follows and cross-sectional views showing each component of a molded interconnecting substrate during each processing step is illustrated from FIG. 3A to FIG. 3G.

As shown in FIG. 3A, an embedded RDL 110 is formed on a molding surface 101 through deposition, patterned electrical plating, dry etching or by lifting process. The embedded RDL 110 includes a plurality of embedded circuitries 111, a plurality of external pads 112, and a plurality of first internal pads 113. Each of the embedded circuitries 111 is connected to a corresponding one of the external pads 112 and a corresponding one of the first internal pads 113. The molding surface 101 is provided by a temporary carrier 10.

As shown in FIG. 3B, an electrical plating seed layer 122 is formed on the temporary carrier 10 by vapor deposition process to at least cover the external pads 112 where the electrical plating seed layer 122 can be stacked layers of Ti/Cu. Then, a photoresist pattern 40 is formed on the electrical plating seed layer 122 on the temporary carrier 10 by photolithography. The openings 41 of the photoresist pattern 40 are aligned to the external pads 112.

As shown in FIG. 3C, a plurality of first conductive pillars 120 are disposed on the external pads 112. The first conductive pillars 120 are formed in the openings of the photoresist pattern 40 through Cu plating processes. After stripping the photoresist pattern 40, the exposed parts of the electrical plating seed layer 122 are etched and removed by dry etching process. The electrical plating seed layer 122 under the first conductive pillars 120 and the seed layer residue rings 123 surrounding the periphery of the external pads 112 remains.

As shown in FIG. 3D, the first chip 130 is die-bonded to the embedded RDL 110 and is electrically connected to the first internal pads 113. The die-bonding method of the first chip 130 is flip-chip die-bonding. The bumps 131 of the first chip 130 are coupled to the first internal pads 113 through the solder paste 132. The first internal pads 113 formed on the molding surface 101 may prevent the flooding of the solder paste 132. The process may include but is not limited to coupling the bumps 131 to the first internal pads 113 through gold-to-gold (Au-to-Au) bonding, gold-to-tin (Au-to-Sn) bonding, Anisotropic Conductive Film (ACF) bonding, Anisotropic Conductive Paste (ACP) bonding, or Non-Conductive Paste (NCP) bonding.

Then, as shown in FIG. 3E, a first molding core 140 is formed on the molding surface 101 to encapsulate the first chip 130 and the first conductive pillars 120. The first molding core 140 has an external surface 141 conforming to the shape of the molding surface 101 and the objects formed on the molding surface 101. The embedded RDL 110 is embedded into the external surface 141 of the first molding core 140. A bottom surface of the embedded circuitries 111, of the external pads 112, and of the first internal pads 113 are coplanar to the external surface 141. The first molding core 140 is formed by loading the temporary carrier 10 between a top mold 51 and a bottom mold 52 and forming a molding compound in the mold chest located between the top mold 51 and the bottom mold 52. The preliminary thickness of the first molding core 140 may be greater than the height of the first conductive pillars 120 to encapsulate the first conductive pillars 120 and the first chip 130.

As shown in FIG. 3F, a grinding head 60 may rotationally grind the top surface of the first molding core 140. In this way, the first molding core 140 may further have a first component-installing surface 142 opposing to the external surface 141 formed through the first planarization process. Each of the first conductive pillars 120 has a pillar-top surface 121 coplanar to the first component-installing surface 142.

As shown in FIG. 3G, the first embossed RDL 150 is formed on the first component-installing surface 142. The first embossed RDL 150 may comprise a plurality of first embossed circuitries 151, a plurality of first pillar-top pads 152, and a plurality of second internal pads 153. Each of the first embossed circuitries 151 may be directly coupled to a corresponding first pillar-top pads 152 and a corresponding second internal pad 153. The first pillar-top pads 152 are aligned and bonded to the first pillar-top surfaces 121. The first embossed RDL 150 is formed on and may extrude from the first molding core 140. The first embossed RDL 150 is fabricated in the same way as the fabrication of the embedded RDL 110. The molded interconnecting substrate 100 is fabricated after removing the temporary carrier 10.

Therefore, according to the manufacture method of the molded interconnecting substrate of the present invention, the RDL layer may not need electrical plating lines and the substrate may not need to go through drilling process, electrical plating of plated through holes, or filling process of plated through holes during substrate manufacture processes.

The molded interconnecting substrate as revealed in the present invention may be a single-core structure or a multi-core structure. According to the second embodiment of the present invention, a cross-sectional view of a molded interconnecting substrate 200 is illustrated in FIG. 4. The objects comprised in the molded interconnecting substrate 200 may have the same names and numbers as mentioned in the first embodiment, and therefore, will no longer be described for brevity. A molded interconnecting substrate 200 comprises an embedded RDL 110, a plurality of first conductive pillars 120, a first chip 130, a first molding core 140, and a first embossed RDL 150.

As shown in FIG. 4, the embedded RDL 110 is formed on a molding surface 101. The embedded RDL 110 includes a plurality of embedded circuitries 111, a plurality of external pads 112, and a plurality of first internal pads 113. Each of the embedded circuitries 111 is coupled to a corresponding external pad 112 and a corresponding first internal pad 113. The first conductive pillars 120 are disposed on the external pads 112. The first chip 130 is die-bonded to the embedded RDL 110 and is electrically connected to the first internal pads 113. The first molding core 140 is formed on the molding surface 101 to encapsulate the first chip 130 and the first conductive pillars 120. The first molding core 140 has an external surface 141 where the embedded RDL 110 is embedded into the external surface 141 of the first molding core 140. Bottom surfaces of the embedded circuitries 111, the external pads 112, and the first internal pads 113 are coplanar to the external surface 141. The first molding core 140 further comprises a first component-installing surface 142 opposing to the external surface 141. Each of the first conductive pillars 120 has a first pillar-top surfaces 121 coplanar to the first component-installing surface 142.

As shown in FIG. 4, the first embossed RDL 150 is formed on the first component-installing surface 142. The first embossed RDL 150 may include a plurality of first embossed circuitries 151, a plurality of first pillar-top pads 152, and a plurality of second internal pads 153. Each of the first embossed circuitries 151 is may be directly coupled to a corresponding first pillar-top pad 152 and a corresponding second internal pad 153. The first pillar-top pads 152 are aligned and bonded to the first pillar-top surfaces 121. The first embossed RDL 150 is formed on the first component-installing surface 142 of the first molding core 140 and may extrude from the first component-installing surface 142 of the first molding core 140.

Furthermore, the molded interconnecting substrate 200 further comprises a second chip 270 die-bonded to the first embossed RDL 150 and electrically connected to the second internal pads 153. A plurality of bumps 271 of the second chip 270 are bonded to the corresponding second internal pads 153.

As shown in FIG. 4, the molded interconnecting substrate 200 further comprises a plurality of second conductive pillars 260, a second molding core 280, and a second embossed RDL 290. The second conductive pillars 260 are disposed on the first pillar-top pads 152. The second molding core 280 is formed on the first component-installing surface 142 to encapsulate the second chip 270 and the second conductive pillars 260. The first embossed RDL 150 is embedded into the second molding core 280. The second molding core 280 has a second component-installing surface 281 opposing to the first component-installing surface 142. Each of the second conductive pillars 260 has a corresponding second pillar-top surface 261 coplanar to the second component-installing surface 281. The second embossed RDL 290 is formed on the second component-installing surface 281. The second embossed RDL 290 includes a plurality of second embossed circuitries 291, a plurality of second pillar-top pads 292, and a plurality of third internal pads 293. The second embossed circuitries 291 are coupled to the corresponding second pillar-top pads 292 and to the corresponding third internal pads 293. The second pillar-top pads 292 are aligned and bonded to the second pillar-top surfaces 261. The second embossed RDL 290 is disposed on and may extrude from the second component-installing surface 281 of the second molding core 280. Hence, the molded interconnecting substrate 200 may be a multi-core structure.

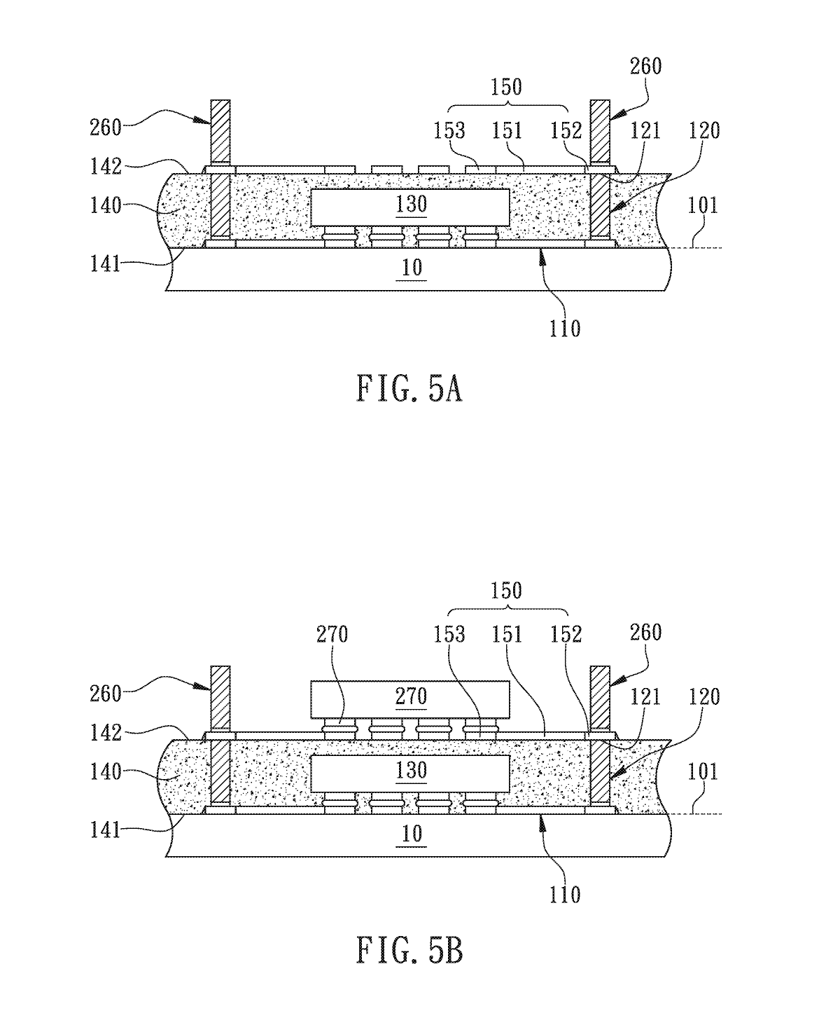

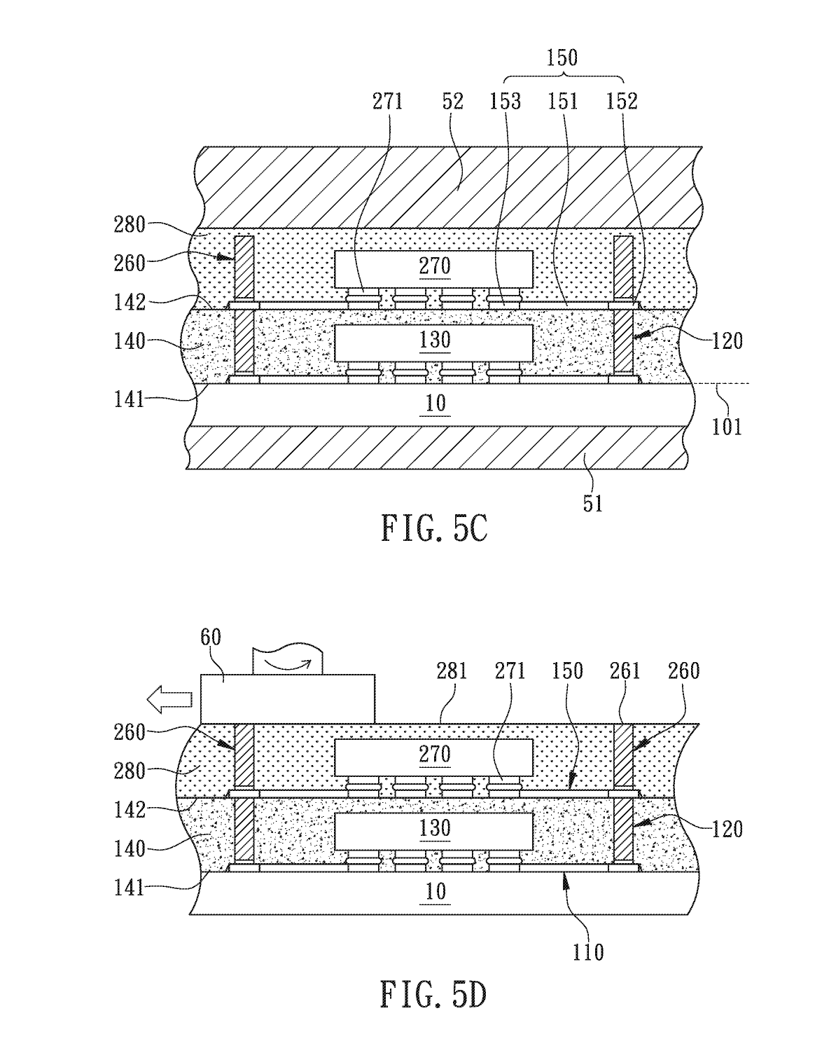

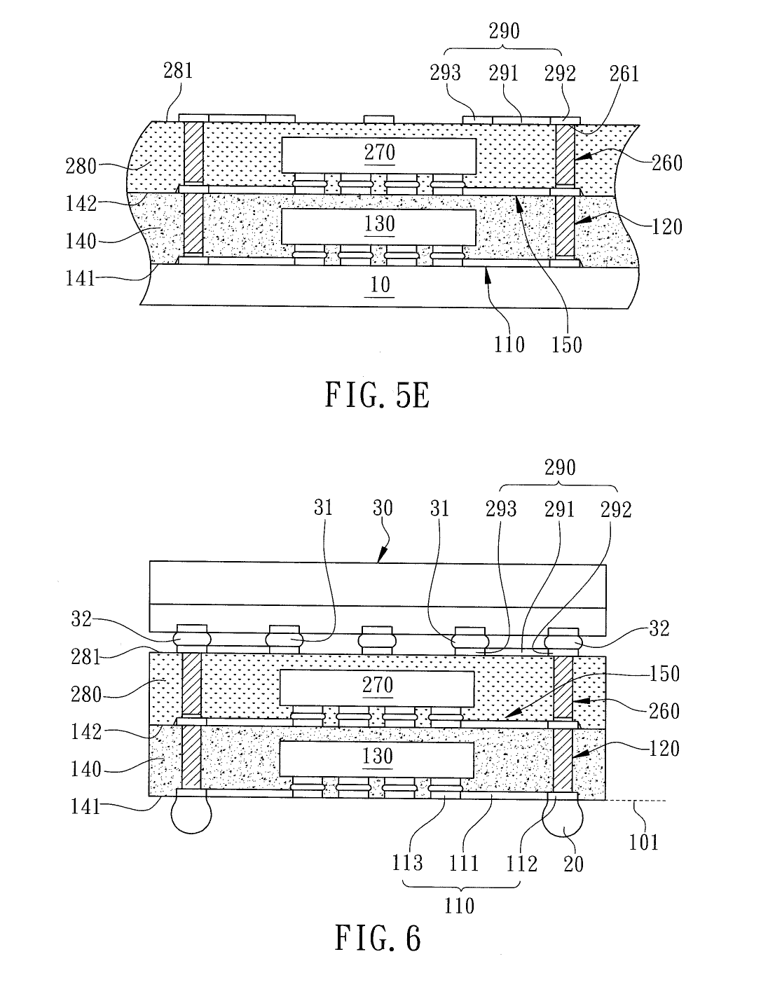

The manufacture method of the molded interconnecting substrate 200 is further described. The manufacture process may be divided into the front-end process and the back-end process. The front-end process may be similar to the method illustrated in FIG. 3A to FIG. 3G Thus, the method illustrated in FIG. 3A to FIG. 3G are no longer described for brevity. The steps of the back-end process are shown in cross-sectional views a molded interconnecting substrate illustrated from FIG. 5A to FIG. 5E.

After FIG. 3G, as shown in FIG. 5A, a plurality of second conductive pillars 260 are disposed on the first pillar-top pads 152 before removing the temporary carrier 10. The deposition process of the second conductive pillars 260 is the same as the deposition process of the first conductive pillars 120.

As shown in FIG. 5B, the second chip 270 is die-bonded to the first embossed RDL 150 and is electrically connected to the second internal pads 153. The bonding process of the second chip 270 is the same as the bonding processes of the first chip 130.

As shown in FIG. 5C, the second molding core 280 is formed on the first component-installing surface 142 to encapsulate the second chip 270 and the second conductive pillars 260. The first embossed RDL 150 is embedded into the second molding core 280. The second molding core 280 is formed in the mold chest between the top mold 51 and the bottom mold 52. The formation process of the second molding core 280 is the same as the formation process of the first molding core 140.

As shown in FIG. 5D, a grinding head 60 is used for the second planarization process. In this way, the second molding core 280 has a second component-installing surface 281 opposing the first component-installing surface 142. Each of the second conductive pillars 260 has a corresponding second pillar-top surfaces 261 coplanar to the second component-installing surface 281.

As shown in FIG. 5E, the second embossed RDL 290 is formed on the second component-installing surface 281. The second embossed RDL 290 includes a plurality of second embossed circuitries 291, a plurality of second pillar-top pads 292, a plurality of third internal pads 293. Each of the second embossed circuitries 291 may be coupled to a corresponding second pillar-top pad 292 and a corresponding third internal pad 293. The second pillar-top pads 292 are aligned and bonded to the second pillar-top surfaces 261. The second embossed RDL 290 is formed on and may extruded from the second component-installing surface 281 of the second molding core 280. The manufacture process of the second embossed RDL 290 are the same as the manufacture process of the first embossed RDL 150. When other components different from the first chip 130 is installed on the second component-installing surface 281, the numbers and the vertical layout of the third internal pads 293 may not correspond to the numbers and the vertical layout of the first internal pads 113. Finally, the temporary carrier 10 is removed. The molded interconnecting substrate 200 as shown in FIG. 4 is fabricated.

FIG. 6 illustrates a cross-sectional view of a stacked microelectronic device implemented using molded interconnecting substrate 200. The molded interconnecting substrate 200 may include an electronic device 30 such as a BGA package mounted on the second embossed RDL 290. The electronic device 30 has a plurality of first electrodes 31 and a plurality of second electrodes 32. The first electrodes 31 are connected to the third internal pads 293. And, the second electrodes 32 are connected to the second pillar-top pads 292. A plurality of external terminals 20 are bonded or disposed on the external pads 112. Individual stacked packages are fabricated after a corresponding singulation process.

As shown in FIG. 2 again, according to the present invention, a molded interconnecting substrate 100 may comprise a first redistribution layer 110, a plurality of first conductive pillars 120, a first chip 130, a first molding core 140, a second redistribution layer 150. The first redistribution layer 110 has a plurality of embedded circuitries 111, a plurality of external pads 112, and a plurality of first internal pads 113, each of the plurality of embedded circuitries 111 configured to electrically couple an external pad 112 to a corresponding first internal pad 113. Each of the first conductive pillars 120 is disposed on a corresponding external pad 112. The first chip 130 is disposed on the first redistribution layer 110. The first chip 130 has a plurality of bumps 131 correspondingly adhered to the plurality of first internal pads 113. The first molding core 140 is configured to encapsulate the first redistribution layer 110, the plurality of first conductive pillars 120, and the first chip 130. And, the first molding core 140 has an external surface 141 and a component-installing surface 142 opposite the external surface 141. Therein, a bottom surface of the first redistribution layer 110 is coplanar to the external surface 141 of the first molding core 140, and a pillar-top surface 121 of the plurality of first conductive pillars 120 is coplanar to the component-installing surface 142. The second redistribution layer 150 is formed to protrude from the component-installing surface 142. The second redistribution layer 150 has a plurality of first embossed circuitries 151, a plurality of first pillar-top pads 152, and a plurality of second internal pads 153. Each of the plurality of first embossed circuitries 151 is configured to electrically couple a first pillar-top pad 152 to a corresponding second internal pad 153. Each of the plurality of first pillar-top pads 152 is directly coupled to a corresponding first conductive pillar 120. The molded interconnecting substrate 100 may further comprise an electrical plating seed layer 122 and a seed layer residue ring 123. The electrical plating seed layer 122 is formed between a first conductive pillar 120 and an external pad 112 and the seed layer residue ring 123 is configured to surround a periphery of an external pad 112.

As shown in FIG. 4 again, in some other embodiments, a molded interconnecting substrate 200 may further comprise a second chip 270, a plurality of second conductive pillars 260, a second molding core 280, a third redistribution layer 290 The second chip 270 is disposed on the second redistribution layer 150. And, the second chip 270 has a plurality of bumps 271 correspondingly adhered to the plurality of second internal pads 153. Each of the plurality of second conductive pillars 260 is disposed on a corresponding first pillar-top pad 152. The second molding core 280 is configured to encapsulate the second redistribution layer 150, the plurality of second conductive pillars 260, and the second chip 270. The second molding core 280 has a second component-installing surface 281 opposite the component-installing surface 142 of the first molding core 140. Each of the plurality of second conductive pillars 260 has a second pillar-top surface 261 coplanar to the second component-installing surface 281. The third redistribution layer 290 is formed to protrude from the second component-installing surface 281 of the second molding core 280. And, the third redistribution layer 290 has a plurality of second embossed circuitries 291, a plurality of second pillar-top pads 292, and a plurality of third internal pads 293. Each of the plurality of second embossed circuitries 291 is configured to electrically couple a second pillar-top pad 292 to a corresponding third internal pad 293. Each of the plurality of second pillar-top pads 292 is directly coupled to a corresponding second conductive pillar 260. The molded interconnecting substrate 200 may further comprise a second electrical plating seed layer 262 formed between a second conductive pillar 260 and a first pillar-top pad 152. And, a second seed layer residue ring 263 is configured to surround a periphery of a first pillar-top pad 152.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

1. A molded interconnecting substrate comprising:
an embedded redistribution layer (RDL) formed on a molding surface, the embedded RDL having a plurality of embedded circuitries, a plurality of external pads, and a plurality of first internal pads, each of the plurality of embedded circuitries being directly coupled to a corresponding external pad and a corresponding first internal pad;
a plurality of first conductive pillars correspondingly disposed on the plurality of external pads;
a first chip die-bonded on the embedded RDL and electrically connected to the first internal pads;
a first molding core formed on the molding surface and configured to encapsulate the first chip and the first conductive pillars, wherein the embedded RDL is embedded in an external surface of the first molding core, wherein each of the plurality of embedded circuitries, each of the plurality of external pads, and each of the plurality of first internal pads has a bottom surface coplanar to the external surface, wherein the first molding core further has a first component-installing surface opposing to the external surface, wherein each of the plurality of first conductive pillars has a corresponding first pillar-top surface coplanar to the first component-installing surface; and
a first embossed RDL formed on the first component-installing surface, the first embossed RDL having a plurality of first embossed circuitries, a plurality of first pillar-top pads, and a plurality of second internal pads, each of the plurality of first embossed circuitries being directly coupled to a corresponding first pillar-top pad and a corresponding second internal pad, wherein each of the plurality of first pillar-top pads is aligned and bonded to a corresponding first pillar-top surface, wherein the first embossed RDL is extruding from the first component-installing surface of the first molding core.

2. The molded interconnecting substrate of claim 1, wherein the first molding core is a single-layer structure formed through molding process and curing process.

3. The molded interconnecting substrate of claim 1, wherein the first chip has a plurality of bumps flip-chip die-bonded to the first internal pads of the embedded RDL.

4. The molded interconnecting substrate of claim 1, wherein the height from the first pillar-top surfaces of the first conductive pillars to the external pads is greater than a disposed chip height of the first chip.

5. The molded interconnecting substrate of claim 1, wherein an electrical plating seed layer is formed between the first conductive pillars and the external pads.

6. The molded interconnecting substrate of claim 5, wherein the electrical plating seed layer includes a plurality of seed layer residue rings encircled the peripheries of the external pads.

7. The molded interconnecting substrate of claim 1, wherein the embedded RDL is formed by reverse deposition of multi-metal layers.

8. The molded interconnecting substrate of claim 1, further comprising a second chip die-bonded to the first embossed RDL and electrically connected to the second internal pads.

9. The molded interconnecting substrate of claim 8, further comprising:
a plurality of second conductive pillars disposed on the first pillar-top pads;
a second molding core formed on the first component-installing surface to encapsulate the second chip and the second conductive pillars, wherein the first embossed RDL is embedded into the second molding core, wherein the second molding core has a second component-installing surface opposing to the first component-installing surface, wherein the second conductive pillars have a plurality of second pillar-top surfaces coplanar to the second component-installing surface; and
a second embossed RDL formed on the second component-installing surface, the second embossed RDL having a plurality of second embossed circuitries, a plurality of second pillar-top pads, a plurality of third internal pads, each of the plurality of second embossed circuitries being directly coupled to a corresponding second pillar-top pad and a corresponding third internal pad, wherein each of the plurality of second pillar-top pads is aligned and bonded to a corresponding second pillar-top surface, wherein the second embossed RDL is extruding from the second component-installing surface of the second molding core.

10. The molded interconnecting substrate of claim 9, further comprising a plurality of external terminals each disposed on a bottom surface of a corresponding external pad.

11. The molded interconnecting substrate of claim 10, further comprising an electronic device mounted on the second embossed RDL, the electronic device having a plurality of first electrodes and a plurality of second electrodes, wherein the first electrodes are connected to the third internal pads and the second electrodes are connected to the second pillar-top pads.

12. A manufacture method of a molded interconnecting substrate comprising:
forming an embedded RDL on a molding surface, wherein the embedded RDL includes a plurality of embedded circuitries, a plurality of external pads, and a plurality of first internal pads, each of the plurality of embedded circuitries being directly coupled to a corresponding external pad and a corresponding first internal pad, wherein the molding surface is provided by a temporary carrier;
disposing a plurality of first conductive pillars on the external pads;
bonding a first chip on the embedded RDL to electrically connect the first chip to the first internal pads;
forming a first molding core on the molding surface configured to encapsulate the first chip and the first conductive pillars, wherein the embedded RDL is embedded into an external surface of the first molding core, wherein each of the plurality of embedded circuitries, each of the plurality of external pads, and each of the plurality of first internal pads has a bottom surface coplanar to the external surface;
planarizing the first molding core through a first planarization process to further have a first component-installing surface opposing to the external surface, wherein each of the plurality of first conductive pillars has a corresponding first pillar-top surface coplanar to the first component-installing surface; and
forming a first embossed RDL on the first component-installing surface, the first embossed RDL having a plurality of first embossed circuitries, a plurality of first pillar-top pads, and a plurality of second internal pads, each of the plurality of first embossed circuitries being directly coupled to a corresponding first pillar-top pad and a corresponding second internal pad, wherein each of the plurality of first pillar-top pads is aligned and bonded to a corresponding first pillar-top surface, wherein the first embossed RDL is extruding from the first component-installing surface of the first molding core.

13. The method of claim 12, further comprising:
disposing a plurality of second conductive pillars on the first pillar-top pads;
bonding a second chip on the first embossed RDL and electrically connecting the second chip to the second internal pads;
forming a second molding core on the first component-installing surface to encapsulate the second chip and the second conductive pillars, wherein the first embossed RDL is embedded into the second molding core;
planarizing the second molding core through a second planarization process to further have a second component-installing surface opposing to the first component-installing surface, wherein the second conductive pillars have a plurality of second pillar-top surfaces coplanar to the second component-installing surface; and
forming a second embossed RDL on the second component-installing surface, the second embossed RDL having a plurality of second embossed circuitries, a plurality of second pillar-top pads, a plurality of third internal pads, each of the plurality of second embossed circuitries being directly coupled to a corresponding second pillar-top pad and a corresponding third internal pad, wherein each of the plurality of second pillar-top pads is aligned and bonded to a corresponding second pillar-top surface, wherein the second embossed RDL is extruding from the second component-installing surface of the second molding core.

14. A molded interconnecting substrate comprising:
a first redistribution layer having a plurality of embedded circuitries, a plurality of external pads, and a plurality of first internal pads, each of the plurality of embedded circuitries configured to electrically couple an external pad to a corresponding first internal pad;
a plurality of first conductive pillars, each disposed on a corresponding external pad;
a first chip disposed on the first redistribution layer, the first chip having a plurality of bumps correspondingly adhered to the plurality of first internal pads;
a first molding core configured to encapsulate the first redistribution layer, the plurality of first conductive pillars, and the first chip, the first molding core having an external surface and a component-installing surface opposite to the external surface, wherein a bottom surface of the first redistribution layer is coplanar to the external surface of the first molding core, wherein a pillar-top surface of the plurality of first conductive pillars is coplanar to the component-installing surface; and
a second redistribution layer formed to protrude from the component-installing surface, the second redistribution layer having a plurality of first embossed circuitries, a plurality of first pillar-top pads, and a plurality of second internal pads, each of the plurality of first embossed circuitries configured to electrically couple a first pillar-top pad to a corresponding second internal pad, each of the plurality of first pillar-top pads is directly coupled to a corresponding first conductive pillar.

15. The molded interconnecting substrate of claim 14, further comprising an electrical plating seed layer formed between a first conductive pillar and an external pad.

16. The molded interconnecting substrate of claim 14, further comprising a seed layer residue ring configured to surround a periphery of an external pad.

17. The molded interconnecting substrate of claim 14, further comprising a second chip disposed on the second redistribution layer, the second chip having a plurality of bumps correspondingly adhered to the plurality of second internal pads.

18. The molded interconnecting substrate of claim 17, further comprising:
a plurality of second conductive pillars, each disposed on a corresponding first pillar-top pad;
a second molding core configured to encapsulate the second redistribution layer, the plurality of second conductive pillars, and the second chip, the second molding core having a component-installing surface opposite the component-installing surface of the first molding core and coplanar to a pillar-top surface of the plurality of second conductive pillars; and
a third redistribution layer formed to protrude from the component-installing surface of the second molding core, the third redistribution layer having a plurality of second embossed circuitries, a plurality of second pillar-top pads, and a plurality of third internal pads, each of the plurality of second embossed circuitries configured to electrically couple a second pillar-top pad to a corresponding third internal pad, each of the plurality of second pillar-top pads is directly coupled to a corresponding second conductive pillar.

19. The molded interconnecting substrate of claim 18, further comprising another electrical plating seed layer formed between a second conductive pillar and a first pillar-top pad.

20. The molded interconnecting substrate of claim 18, further comprising another seed layer residue ring configured to surround a periphery of a first pillar-top pad.
